(19) United States
(12) Patent Application Publication
(10) Pub. No.: US 2025/0103097 A1
(43) Pub. Date: Mar. 27, 2025

(54) ELECTRONIC DEVICE WITH LIGHTWEIGHT FACIAL INTERFACE

(71) Applicant: Apple Inc., Cupertino, CA (US)

(72) Inventors: Paul X. Wang, Cupertino, CA (US); Adam Y. Kollgaard, San Jose, CA (US)

(21) Appl. No.: 18/826,133

(22) Filed: Sep. 5, 2024

Related U.S. Application Data
(60) Provisional application No. 63/585,563, filed on Sep. 26, 2023.

(51) Int. Cl. G06F 1/16

(52) U.S. Cl. CPC G06F 1/163

(57) ABSTRACT

A head-mountable device includes a display frame, an optical component, a facial interface, and a strap. The optical component is disposed within the display frame. The facial interface is connected to the display frame and includes a lattice structure. The strap connects to the display frame.

### CROSS-REFERENCE TO RELATED APPLICATION

This application claims the benefit of U.S. Provisional Patent Application No. 63/585,563, filed 26 Sep. 2023, and entitled “ELECTRONIC DEVICE WITH LIGHTWEIGHT FACIAL INTERFACE,” the entire disclosure of which is hereby incorporated by reference.

### FIELD

The described embodiments relate generally to electronic devices. More particularly, the present embodiments relate to facial interfaces of electronic devices.

### BACKGROUND

Recent advances in portable computing have enabled head-mountable devices that provide augmented reality and virtual reality (AR/VR) experiences to users. Such head-mountable devices can include various components such as a display, a viewing frame, lenses, optical components, a battery, motors, speakers, and other components. These components can operate together to provide an immersive user experience. In particular, head mountable-devices can include components that help provide a distraction-free setting by at least partially blocking or sealing out the outer environment (e.g., ambient light). This can be a challenging design aspect as users of head-mountable devices have different head sizes, head shapes, and contours of facial features. Therefore, there is a need for a head-mountable device with a lightweight and highly conformable facial interface.

### SUMMARY

In at least one example, a head-mountable device can include a display frame, an optical component disposed within the display frame, a facial interface connected to the display frame and having a lattice structure, and a strap connected to the display frame.

In one example of the head-mountable device, the lattice structure can have a geometry or pattern configuration of an auxetic structure, a honeycomb structure, an adjoining sphere structure, or a custom structure based on a stress-strain mapping.

In one example of the head-mountable device, the lattice structure can include an elastomer material.

In one example of the head-mountable device, the lattice structure can include a first material and a second material.

In one example, the head-mountable device can include an insert embedded within the lattice structure.

In one example of the head-mountable device, a portion of the lattice structure can include a first set of directional properties and a second set of directional properties different from the first set of directional properties.

In one example, the head-mountable device can include a rigid bumper connected to the display frame and positioned between the display frame and the facial interface. The rigid bumper can define a fixed gap between the optical component and the facial interface.

In one example of the head-mountable device, the lattice structure is a first lattice structure and further includes a second lattice structure interchangeable with the first lattice structure. In certain examples, the first lattice structure and the second lattice structure correspond with the rigid bumper.

In one example of the head-mountable device, the facial interface is removably attached to the rigid bumper.

In one example of the head-mountable device, a first portion of the lattice structure can include a base. A second portion of the lattice structure can include a customized portion.

In at least one example, a wearable apparatus can include a display housing, a display positioned within the housing, and a facial interface connected to the display housing. The facial interface can include a layered material having a repeating geometric arrangement, the layered material having a first portion having a first set of directional properties and a second portion having a second set of directional properties different from the first set of directional properties.

In one example of the wearable apparatus, the repeating geometrical arrangement can include a C-shaped rib.

In one example of the wearable apparatus, the repeating geometrical arrangement can include a set of vertical beams positioned substantially parallel relative to a contact surface of the facial interface configured to engage a human face.

In a further example of the wearable apparatus, the set of vertical beams is a first set of vertical beams, and the repeating geometrical arrangement can include a second set of vertical beams stacked relative to the first set of vertical beams. The first set of vertical beams and the second set of vertical beams can be configured to laterally buckle in response to a force.

In one example of the wearable apparatus, the facial interface includes a single-piece unit.

In at least one example, a wearable electronic device can include a head-mountable display, an insert, and a facial interface including a combination of integrally connected layers defining an ordered pattern disposed around a portion of the insert.

In one example of the wearable electronic device, the insert can include a magnet, an attachment member, or a structural member.

In one example of the wearable electronic device, the insert can be embedded in the facial interface.

In one example of the wearable electronic device, the facial interface can be stretched over the insert.

In one example of the wearable electronic device, the facial interface includes a first material, and the insert can include a second material that differs from the first material.

### BRIEF DESCRIPTION OF THE DRAWINGS

The disclosure will be readily understood by the following detailed description in conjunction with the accompanying drawings, wherein like reference numerals designate like structural elements, and in which:

FIG. 1 illustrates a top view profile of a head-mountable device worn on a user head 101, according to one example;

FIG. 2A illustrates a side view of the head-mountable device of FIG. 1;

FIG. 2B illustrates a front view of the head-mountable device of FIG. 1;

FIG. 3A illustrates a top view of a head-mountable device with a facial interface including a lattice structure, according to one example;

FIG. 3B illustrates a rear view of the head-mountable device of FIG. 3A, according to one example;

FIG. 3C illustrates a cross-sectional view of the head-mountable device of FIG. 3A, according to one example;

FIG. 4 illustrates a top view of a head-mountable device with engagement mechanisms, according to one example;

FIG. 5 illustrates a top view of a head-mountable device with a facial interface including a first material and a second material, according to one example;

FIG. 6 illustrates a top view of a head-mountable device with a facial interface including an insert, according to one example;

FIG. 7 illustrates a rear view of a head-mountable device with a facial interface including vertical beams, according to one example;

FIG. 8A illustrates a rear view of a head-mountable device with a facial interface including a first set of vertical beams and a second set of vertical beams in a non-deformed configuration, according to one example;

FIG. 8B illustrates a rear view of the head-mountable device of FIG. 8A with the facial interface including the first set of vertical beams and the second set of vertical beams in a deformed configuration, according to one example;

FIG. 9 illustrates a rear view of a head-mountable device with a facial interface including C-shaped ribs, according to one example;

FIG. 10A illustrates a three-dimensional (3D) lattice structure with a geometry or pattern configuration of a honeycomb structure;

FIG. 10B illustrates a 3D lattice structure with a geometry or pattern configuration of a beam structure;

FIG. 10C illustrates a 3D lattice structure with a geometry or pattern configuration of a gyroid lattice structure;

FIG. 10D illustrates a 3D lattice structure with a geometry or pattern configuration of a stochastic lattice;

FIG. 11A illustrates a 3D lattice structure in the absence of a deforming force; and

FIG. 11B illustrates the 3D lattice structure of FIG. 11A under the influence of a deforming force F.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

The following disclosure relates generally to electronic devices, specifically a head-mountable electronic device (or head-mountable device). In at least one example, a head-mountable device can include a viewing frame and a securement arm (or strap/band) extending from the viewing frame. Examples of head-mountable electronic devices can include virtual reality or augmented reality devices that include an optical component. In the case of augmented reality devices, optical eyeglasses or frames can be worn on the head of a user such that optical windows, which can include transparent windows, lenses, or displays, can be positioned in front of the user's eyes. In another example, a virtual reality device can be worn on the head of a user such that a display screen is positioned in front of the user's eyes. The viewing frame can include a housing (e.g., a display housing or display frame) or other structural components supporting the optical components, for example lenses or display windows, or various electronic components.

Additionally, a head-mountable electronic device can include one or more electronic components used to operate the head-mountable electronic device. These components can include any components used by the head-mountable electronic device to produce a virtual or augmented reality experience. For example, electronic components can include one or more projectors, waveguides, speakers, processors, batteries, circuitry components including wires and circuit boards, or any other electronic components used in the head-mountable device to deliver augmented or virtual reality visuals, sounds, and other outputs. The various electronic components can be disposed within the electronic component housing. In some examples, the various electronic components can be disposed with in or attached to one or more of the display frame, the electronic component housing, or the securement arm.

More particularly, the disclosure relates to facial interfaces of a head-mountable device (HMD). A facial interface refers to a seal that is sandwiched between the HMD and the user's face. In more detail, the following disclosure relates to facial interfaces that are lightweight and conformable in order to optimize the user experience. Such lightweight and conformable facial interfaces allow the HMD to comfortably conform to the user's face and accommodate the user's unique head size and shape.

The lightweight and conformable interface can be achieved via additive manufacturing (e.g., three-dimensional (3D) printing), whereby an object is fabricated by addition and bonding of successive thin layers of materials. Additive manufacturing can enable fabrication of facial interfaces that are lightweight and pliant (in some cases, with negligible weight and stiffness), for example by selecting various materials, lattice structures, and lattice densities.

Furthermore, additive manufacturing can allow for easy and cost-effective customizability of the facial interfaces. Facial interfaces can be fabricated to have a variety of shapes, contours, and stiffness to accommodate different users' various head shapes, sizes, and facial contours. In certain examples, at least a portion of a facial interface (e.g., an outer, skin-facing layer) can be customized on a user-by-user basis for more control and a tailored fit to specific users.

In at least one example, the facial interfaces disclosed herein can be separate and discrete from structural members of a head-mountable device. For example, a facial interface of the present disclosure can be connected to or at least in contact with a rigid bumper that can help maintain structural integrity of the head-mountable device. In such examples, a facial interface can be sized and shaped to accommodate one or more rigid bumpers. However, despite the facial interface being connected to or in contact with the rigid bumper, the facial interface can be functionally decoupled from the rigid bumper so that the facial interface can have increased conformability and help provide a better fit and more comfort to the user.

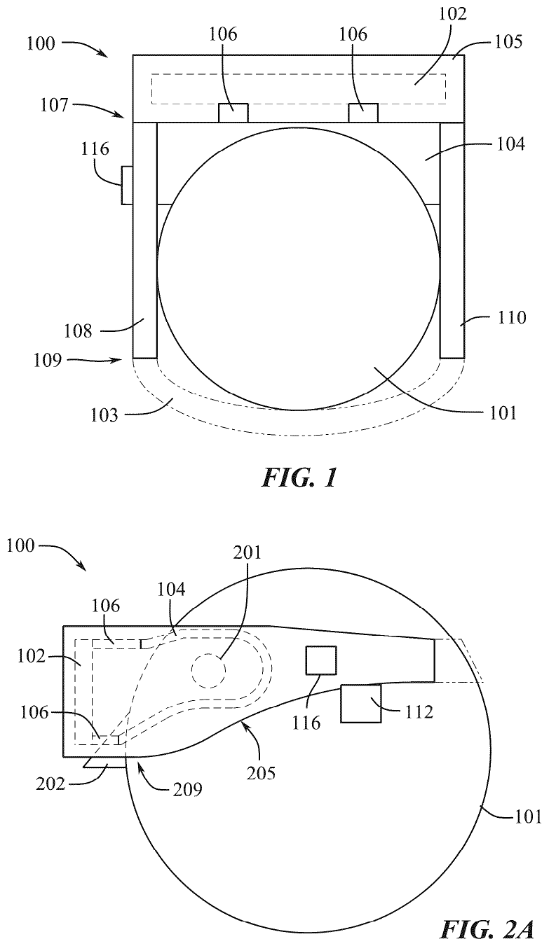

These and other embodiments are discussed below with reference to FIGS. 1-11B. However, those skilled in the art will readily appreciate that the detailed description given herein with respect to these Figures is for explanatory purposes only and should not be construed as limiting. Furthermore, as used herein, a system, a method, an article, a component, a feature, or a sub-feature comprising at least one of a first option, a second option, or a third option should be understood as referring to a system, a method, an article, a component, a feature, or a sub-feature that can include one of each listed option (e.g., only one of the first option, only one of the second option, or only one of the third option), multiple of a single listed option (e.g., two or more of the first option), two options simultaneously (e.g., one of the first option and one of the second option), or combination thereof (e.g., two of the first option and one of the second option).

FIG. 1 illustrates a top view profile of a head-mountable device 100 worn on a user head 101, according to one example. While the present systems and methods are described in the context of a head-mountable device 100, the systems and methods can be used with any wearable apparatus, wearable electronic device, or any apparatus or system that can be physically attached to a user's body, but are particularly relevant to an electronic device worn on a user's head.

The head-mountable device 100 can include an optical component 102 (e.g., one or more optical lenses or display screens in front of the eyes of the user). The optical component 102 can include a display/screen for presenting augmented reality visualizations, a virtual reality visualization, or other suitable visualization. The optical component 102 can be part of an optical module, which can include sensors, cameras, light emitting diodes, an optical housing, a cover glass, sensitive optical elements, etc. The optical component 102 can be disposed on or within a display frame 105. In other terms, the display frame 105 can be a display housing which houses the optical components 102. For example, a display of the optical component 102 can be positioned within the display housing.

The head-mountable device 100 can include arm(s), such as arm 108 and arm 110. The arms 108, 110 can secure the head-mountable device 100 to the user's head 101. The arms 108, 110 have a proximal end 107 and a distal end 108. The proximal end 107 is connected to the display frame 105. The arms 108, 110 are connected to the display frame 105 and extend distally toward the rear of the head. The arms 108, 110 are configured to secure the display in a position relative to the user head 101 (e.g., such that the optical component 102 is maintained in front of a user's eyes). For example, the arms 108, 110 extend over the user's ears 112. In certain examples, the arms 108, 110 rest on the user's ears 112 to secure the head-mountable device 100 via friction between the arms 108, 110 and the user head 101. For example, the arms 108, 110 can apply opposing pressures to the sides of the user head 101 to secure the head-mountable device 100 to the user head 101. In at least one example, a strap 103 can be connected to the distal ends of both of the arms 108, 110. The strap 103 can provide additional support to secure the head-mountable device 100 to the user's head 101, for example, by wrapping around the back of the user's head 101. The strap 103 can compress the head-mountable device 100 against the user head 101. In particular examples, the strap 103 is connected to at least the frame of the display 102 or the facial interface 104.

The head-mountable device 100 can include an electronics pod 116. As depicted in FIG. 1, the electronics pod 116 can be disposed on the arm 108. However, in other examples, the electronics pod 116 can be disposed on the arm 110, the strap 103, the display frame 105, or elsewhere on the head-mountable device 100. The electronics pod 116 can include various electronic components, such a controllers, microcontrollers, processors, memory, batteries, power port(s), etc.

The head-mountable device 100 includes a facial interface 104. The facial interface 104 is at least partially disposed on an inner surface of the head-mountable device 100. As used herein, an “inner surface” refers to an exterior surface of the head-mountable device 100 that is oriented to face towards (or contact) a human face or skin. By contrast, as used herein, an “outer surface” refers to an exterior surface of the head-mountable device 100 that outwardly faces the ambient environment.

As used herein, the term “facial interface” refers to a portion of the head-mountable device 100 that engages a user face via direct contact. In particular, a facial interface includes portions of the head-mountable device 100 that conform to (e.g., compress against) regions of a user face. For example, a facial interface can include a pliant (or semi-pliant) face track that spans the forehead, wraps around the eyes, contacts the zygoma and maxilla regions of the face, and bridges the nose. In addition, a facial interface can include various components forming a structure, webbing, cover, fabric, or frame of a head-mountable device disposed between the display frame 105 and the user skin. In particular implementations, a facial interface can include a seal (e.g., a light seal, environment seal, dust seal, air seal, etc.). It will be appreciated that the term “seal” can include partial seals or inhibitors, in addition to complete seals (e.g., a partial facial interface where some ambient light is blocked and a complete facial interface where all ambient light is blocked when the head-mountable device is donned).

In some examples, the facial interface 104 can include a lattice structure, as will be described in reference to the remaining Figures. As used herein, a lattice structure refers to an interlaced design, a grid design, a framework, a three-dimensional arrangement, or a repeat pattern that can fill a volume and/or conform to a surface. For example, a lattice structure can include one or more beams, surfaces, plates, or cells that fit together following an ordered or repeating pattern/geometrical arrangement (e.g., a symmetrical pattern, a grid pattern, a fixed-shaped pattern, a fractal, a spiral pattern, a meander pattern, a tessellation pattern, a wave pattern, a crystal pattern, a mathematical pattern, or a stochastic pattern). A lattice structure can have various material properties, including directional material properties. For instance, a lattice structure can include one or more portions with isotropic material properties and/or one or more portions with anisotropic material properties. In particular examples, a lattice structure includes material properties (e.g., modulus, stiffness, beam diameter, unit cell density, anisotropy, etc.) that can be tuned or adjusted according to various design factors. In these or other examples, a lattice structure can be manufactured in a variety of ways, including via additive manufacturing or 3D printing.

In some examples, a facial interface can include a combination of integrally connected layers (e.g., that define an ordered pattern discussed above). As used herein, the term integrally connected layers refers to two or more layers that are fixedly or irremovably connected to each other. Examples of integrally connected layers can include stacked layers, printed layers (e.g., 3D printed layers), adhered layers, bonded layers, welded layers, molded layers, etc. In the example of 3D printing, integrally connected layers can include rows, steps, filaments, ribs, etc. that are added one on top of the other (i.e., layer by layer) during the printing process. In certain examples, the integrally connected layers can be visible (e.g., as seams, ridges, lines, rings, or timber-like grains). In other examples, the integrally connected layers can be visually hidden or obscured through various methods (e.g., sanding, painting, coating, sand blasting, superficially fusing/melting a thin outer layer, etc.).

The facial interface 104 can be fabricated via additive manufacturing (e.g., 3D printing) to have a geometry or pattern configuration of an auxetic structure (e.g., a structure which, when stretched along one direction, expands in a perpendicular direction), a honeycomb structure, an adjoining sphere structure, or the like. The facial interface 104 can be fabricated using elastomer materials (e.g., materials that return to their original shapes after being stretched), multiple materials, anisotropic materials, etc. Additive manufacturing can enable a large range of customizability of facial interfaces to accommodate unique head sizes, head shapes, and facial contours.

In at least one example, the head-mountable device can include one or more rigid bumpers (e.g., bumper(s) 106). As used herein, the term “rigid bumper” refers to structural post, support, backstop, bulwark, absorber, buffer, column, or block. In these or other examples, a rigid bumper can be positionally fixed relative to other components of the head-mountable device 100. In particular, a rigid bumper can comprise a stiff, rigid, or hardened material (e.g., for resisting impact forces or bending moments, transferring applied loads, or providing a fixed datum). In certain examples, a rigid bumper includes a metal material (e.g., aluminum), an engineering plastic material, a fiber reinforced plastic material, etc. Thus, in particular examples, the bumper(s) 106 can include a structural post that can extend from the display frame 105. The bumper(s) 106 can also abut and/or be at least partially embedded within the facial interface 104.

In more detail, the bumper(s) 106 can be connected to the display frame 105 and positioned between the display frame 105 and the facial interface 104. The facial interface 104 can be connected to the display frame 105. In some examples, the bumper(s) 106 defines a fixed gap between the optical component 102 and the facial interface 104.

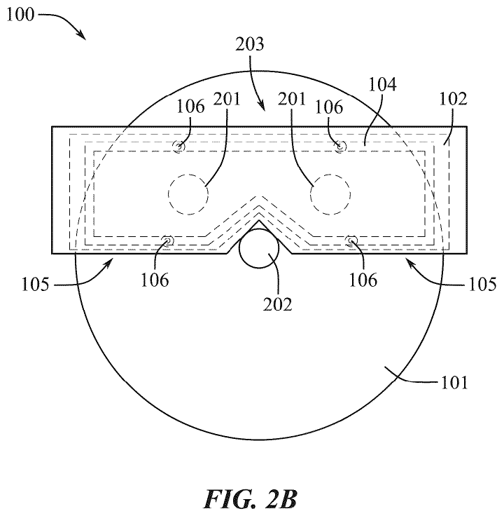

Any of the features, components, and/or parts, including the arrangements and configurations thereof shown in FIG. 1 can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 1. Additional views of the head-mountable device are provided in reference to FIGS. 2A-2B.

FIGS. 2A-2B respectively illustrate side and front view profiles of an example of the head-mountable device 100. As discussed above, the head-mountable device 100 includes the optical component 102, the display frame 105, the facial interface 104, and the bumper(s) 106. As shown in FIGS. 2A-2B, the facial interface 104 can wrap around the eyes 201, bridge the nose 202, span the forehead 203, and contact the zygoma region 205 and maxilla region 209 of the face.

As used herein, the term “forehead region” refers to an area of a human face between the eyes and the scalp of a human. Additionally, the term “zygoma region” refers to an area of a human face corresponding to the zygomatic bone structure of a human. Similarly, the term “maxilla region” refers to an area of a human face corresponding to the maxilla bone structure of a human.

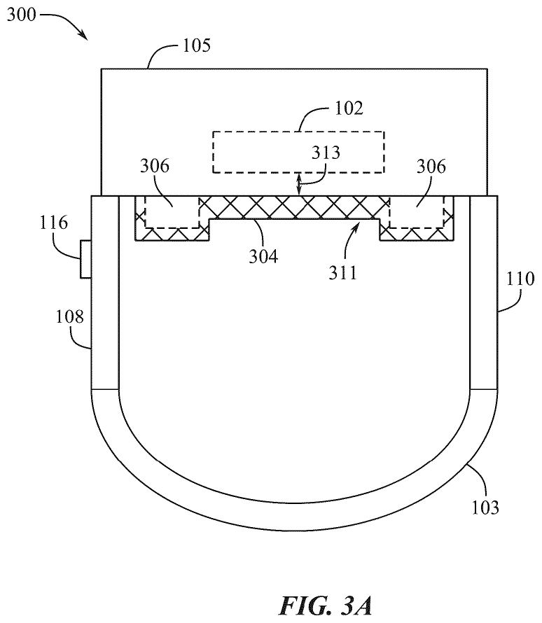

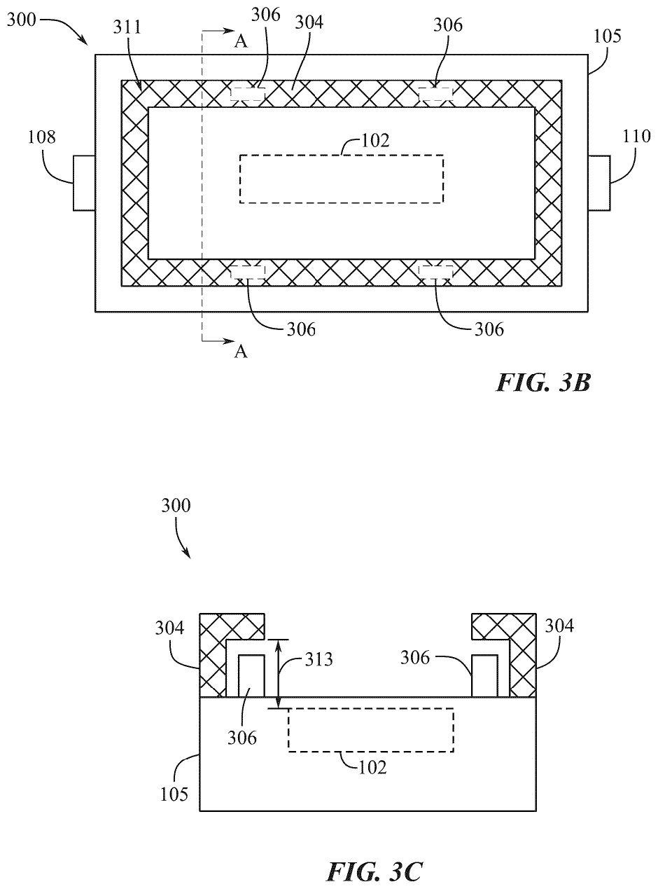

Any of the features, components, and/or parts, including the arrangements and configurations thereof shown in FIGS. 2A-2B can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIGS. 2A-2B. Additional details of facial interfaces fabricated via additive manufacturing are described below in reference to FIGS. 3A-3C.

FIGS. 3A-3C illustrate a top view, a rear view, and a cross-sectional view of a head-mountable device 300 with a facial interface 304 including a lattice structure 311, according to one example. As used herein, a top view refers to a view of the head-mountable device 300 as viewed from the top of the head 101, a rear view refers to a view of the head-mountable device 300 as viewed from behind the head 101, and the cross-sectional view is viewed along the line A-A indicated in FIG. 3B. Although not all components are necessarily shown, the head-mountable device 300 is the same as or similar to the head-mountable device 100 of FIGS. 1-2B, as noted by similar reference numbers.

In at least one example, the head-mountable device 300 includes rigid bumper(s) 306. The bumper(s) 306 can be connected to the display frame 105 and positioned between the display frame 105 and the facial interface 304, which is connected to the display frame 105. The bumper(s) 306 can be a rigid, or non-flexible component that defines a fixed gap 313 between the optical component 102 and the facial interface 304. For example, at least part of the bumper(s) 306 can be positioned between the optical component 102 and the facial interface 304 such that, even when compressed by the head 101, the facial interface 304 is prevented from contacting the optical component 102.

The lattice structure 311 can be a 3D printed lattice structure and is indicated in FIGS. 3A-3C with cross-hatched shading. The lattice structure 311 can by manufactured to have various properties such as to accommodate a user's specific head shape, head size, and facial contours. As will be further described in reference to the remaining Figures, the lattice structure 311 can have a geometry or pattern configuration of an auxetic structure, a honeycomb structure, an adjoining sphere structure, or a custom structure based on a stress/straining mapping. In some examples, a lattice structure 311 can include a combination of the above-listed or other lattice structures.

In at least one example, the lattice structure 311 can include an anisotropic lattice structure. Thus, at least a portion of the lattice structure 311 can include a first set of directional properties and a second set of directional properties different from the first set of directional properties. In other terms, anisotropic lattice structures can exhibit different properties along different directions relative to the structure. Anisotropic lattice structures can provide the facial interface 304 with rigidity in one or more directions while being compressible and conformable in the other directions. In one example, the facial interface 304 can be rigid along a top-to-bottom direction and a side-to-side direction of the head 101 to prevent sagging of the facial interface 304 when the head-mountable device is worn by the user. Additionally or alternatively, the facial interface 304 can be compressible and conformable along a front-to-back direction of the head 101 allowing the facial interface 304 to adapt the user's specific head shape and facial contours.

In at least one example, the lattice structure can include an elastomer material. An elastomer material can be characterized by its ability to return to its original configuration after an applied deforming stress (force) is removed.

As illustrated in FIG. 3B, in some examples, the facial interface 304 can span approximately along an outer perimeter of the display frame 105. The facial interface 304 can contact the user's face and can at least partially encompass the bumper(s) 306. The bumper(s) 306 can be located between the facial interface 304 and the display frame 105 so as to define a fixed gap 313 between the user's face and the optical component 102.

Although illustrated as being distributed along the perimeter of the facial interface 304, in some examples, the bumper(s) 306 can have different configurations. In one example, the bumper(s) 306 can be located at regions corresponding solely to regions of the forehead 203 (shown in FIG. 2A-2B), the zygoma region 205, or the maxilla region 209. In other examples, the bumper(s) 306 can be located at multiple regions corresponding to the forehead 203 (shown in FIG. 2A-2B), the zygoma region 205, or the maxilla region 209. In a particular implementation, the bumper(s) 306 are positioned at center and oblique regions of the forehead 203, and at the maxilla region 209.

Although illustrated as having four bumpers 306, in other examples, the head-mountable device 300 can have more or less bumper(s), such as one, two, three, five, six, and so forth. In some examples, a bumper can be continuous and can run along the perimeter of the head-mountable device, following the facial interface. The above-listed configuration of bumpers are examples and are not intended to be a fully inclusive list of possible configurations.

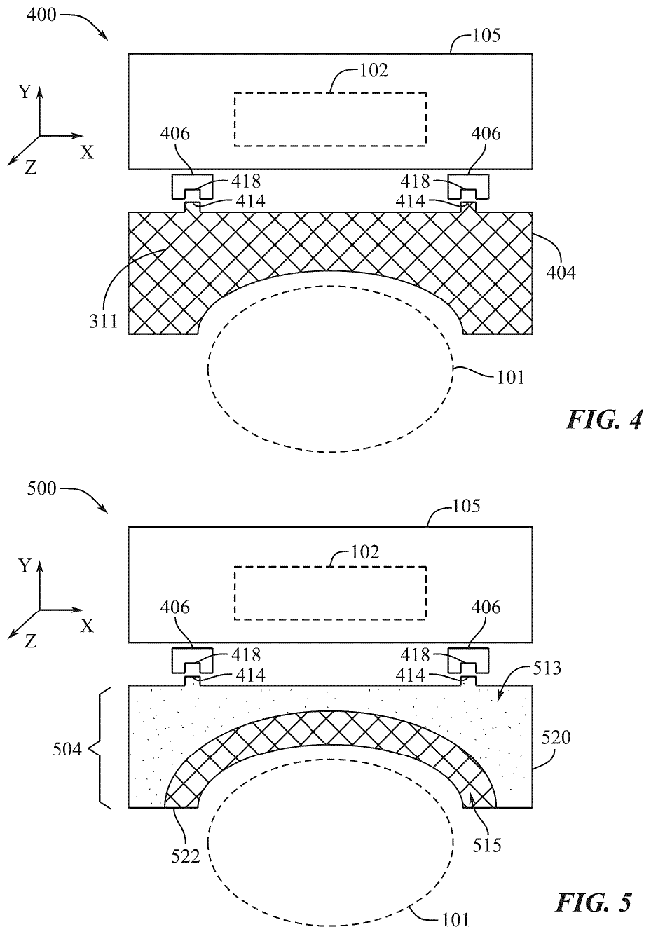

Any of the features, components, and/or parts, including the arrangements and configurations thereof shown in FIGS. 3A-3C can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIGS. 3A-3C. Additional details of internal structures of facial interfaces fabricated via additive manufacturing are described below in reference to FIGS. 4-11. In particular, details relating to mechanical couplings between the facial interface and the bumper(s) are described in reference to FIG. 4.

FIG. 4 illustrates a top view of a head-mountable device 400 with engagement mechanisms 414 and 418, according to one example. Although not all components are necessarily shown, the head-mountable device 400 is the same as or similar to the head-mountable device 300 of FIGS. 3A-3C, as noted by similar reference numbers. For example, the head-mountable device 400 can include an optical component 102, a display frame 105, a facial interface 404, and bumper(s) 406. A Cartesian (rectangular) coordinate system is indicated in FIGS. 4-9 for clarity of the following description. The Cartesian coordinate system indicates the X-direction as from “side-to-side” of the user's head 101, the Y-direction as from “front-to-back” of the user's head 101, and the Z-direction as from “top-to-bottom” of the user's head 101.

In at least one example, the facial interface 404 can include engagement mechanism(s) 414. Similarly, the bumper(s) 406 can include engagement mechanism(s) 418 configured to receive the engagement mechanism(s) 414. The engagement mechanism(s) 414 and 418 can be coupled to prevent translation or shifting of the facial interface 404 relative to the bumper(s) 406 along the X-direction (e.g., side-to-side relative to the user's head 101) and/or along the Z-direction (e.g., top-to-bottom relative to the user's head 101).

The engagement mechanism(s) 414 and 418 can include a bumps and recesses which fit relative to each other. Additionally or alternatively, the engagement mechanism(s) 414 and 418 can include other mating features, interlocking features, or attachment features such as snap buttons, magnets, hook-and-loop fasteners (Velcro®), adhesives, etc. Further, the engagement mechanisms(s) 414 and 418 can be configured to either be temporary, such that the facial interface 404 can be removed and/or interchanged, or can be configured to be permanent.

In the case wherein the facial interface 404 is removable from the bumper(s) 406, the lattice structure 311 can be interchangeable with different sized lattice structures. Each of the lattice structures and different structures can correspond to a size and shape of the rigid bumper(s) 406. For example, a facial interface with a larger lattice structure can require larger bumper(s) and/or engagement mechanisms 414 and 418 in order to be secured.

In at least one example, the facial interface 404 includes a single-piece unit, as depicted in FIG. 4 (in contrast to the example illustrated in FIG. 5 below). In such a case, the facial interface 404 can be additively manufactured using a single material having a single lattice structure. A single-piece unit can be continuous from side-to-side and top-to-bottom.

In at least one example, a portion of the lattice structure 411 can be an articulating portion. For example, the lattice structure 411 can be attached or fixed to at least one of the bumper(s) 406 or the display frame 105. Upon application of a compression force, for example, from a user's head 101, the lattice structure 411 can rotate with respect to the display frame 105 to accommodate facial contours of the user. In some examples, the facial interface 404 can include a structure which can break or snap upon an initial use of the head-mountable device 400, allowing the articulating portion to articulate and flexibly move in response to compression against a user's face.

Any of the features, components, and/or parts, including the arrangements and configurations thereof shown in FIG. 4 can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 4. Additional details relating to facial interfaces with multiple materials are described in reference to FIG. 5.

FIG. 5 illustrates a top view of a head-mountable device 500 with a facial interface 504 including a first material 513 and a second material 515, according to one example. Although not all components are necessarily shown, the head-mountable device 500 is the same as or similar to the head-mountable device 400 of FIG. 4, as noted by similar reference numbers. For example, the head-mountable device 500 can include an optical component 102, a display frame 105, and bumper(s) 406. The head-mountable device 500 can include the facial interface 504 with a lattice structure including a first portion having the first material 513 and a second portion having the second material 515.

In at least one example, the first portion of the lattice structure includes a standard base 520. The standard base 520 can be standardized among one or more head-mountable devices. For example, each head-mountable device 500 can be manufactured to have identical standard bases 520. Similar to the head-mountable device 400 of FIG. 4, the standard base 520 can be removably or permanently fixed to the bumper(s) 406. The standard base 520 can provide a structural support which can at least partially define the facial interface 504. The term “standard base” can refer to a portion of the facial interface 504 that is a foundation portion, a common portion, or a vanilla portion that is the same underlying portion for all facial interfaces.

In at least one example, the second portion of the lattice structure includes a customized portion 522. A “customized portion” can include tailored portions, user-specific portions, fitted portions, personalized portions, made-to-order, predetermined portions, sized portions (e.g., small, medium, large portions), etc. The customized portion 522 can be customized among one or more head-mountable devices. For example, each head-mountable device 500 can be manufactured to have unique customized portions 522. The customized portion 522 can be more flexible or conformable (e.g., in comparison to the standard base 520) to accommodate unique head sizes, shapes, and/or facial contours of the head 101. By making the customized portion 522 customizable, the head-mountable device 500 can be more efficiently and cost-effectively customized to accommodate individual heads of users (rather than customizing an entirety of the facial interface 504). In one example, the customized portion 522 can be permanently fixed or coupled to the standard base 520 at the time of manufacturing of the head-mountable device 500. In other examples, the customized portion 522 can be removably attached to the standard base 520. As such, customized portions 522 can be interchangeable, allowing for the facial interface 504 to be changed depending on the individual user. This feature can allow for a single head-mountable device to accommodate multiple users.

In at least one example, the standard base 520 can include an isotropic lattice structure, which provides rigidity in each of the X-, Y-, and Z-directions. Alternatively, the second portion (e.g., the customized portion 522) can have a first set of directional properties and a second set of directional properties different from the first set of directional properties. In other words, the customized portion 522 can include an anisotropic lattice structure. The anisotropy of the lattice structure of the customized portion 522 can be rigid (or substantially rigid) in the X-direction and the Z-direction. Further, the anisotropy of the lattice structure of the customized portion 522 can be compressible (compared to the standard base 520) in the Y-direction, allowing the facial interface 504 to conform to the user's face.

In at least one example, the facial interface 504 can be additively manufactured in a single process. The standard base 520 can be 3D printed using a first material having a first lattice structure while the customized portion 522 can be 3D printed using a second material having a second lattice structure. In other examples, the standard base 520 can be 3D printed using a first material having a first lattice structure while the customized portion 522 can be 3D printed using the same first material having a second lattice structure different from the first lattice structure. In other examples, the standard base 520 can be 3D printed using a first material having a first lattice structure while the customized portion 522 can be 3D printed using a second material different from the first material but having the same first lattice structure.

Although the facial interface 504 of FIG. 5 is illustrated as including two materials, in other examples, a facial interface can include additional materials, such as three, four, five, etc. The materials can be repeated (e.g., a first layer can include a first material, a second layer can include a second material, a third layer can include the first material, etc.). Otherwise, the materials can be mutually unique. Furthermore, each layer of material can be fabricated to have various thicknesses. For example, a layer of material that contacts the user's head 101 can be thicker than a layer of material that contacts the bumper(s) 406 in order to conform to the user's head and face. Each layer (e.g., portion) can have any of the properties described above with respect to the first portion (the standard base 520) or the second portion (the customized portion 522).

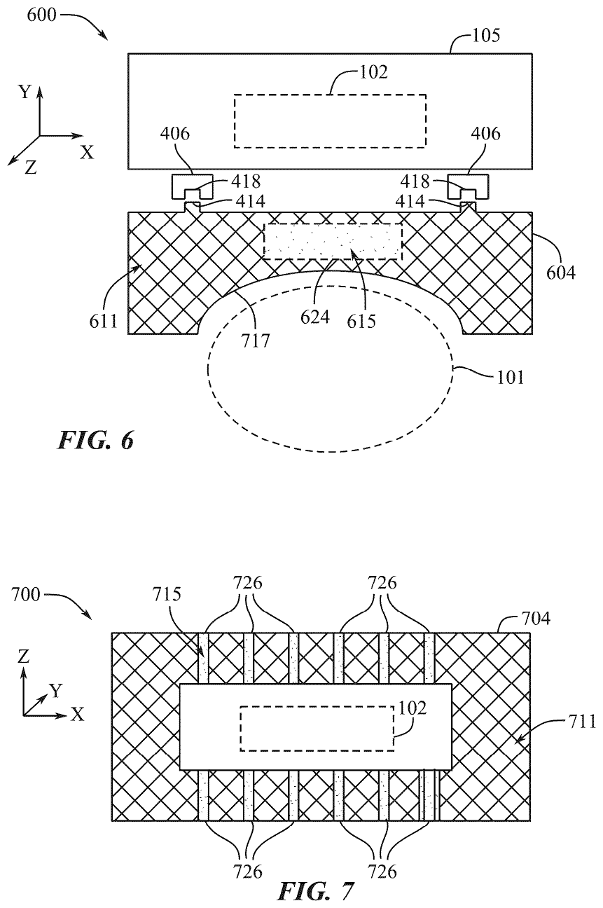

Any of the features, components, and/or parts, including the arrangements and configurations thereof shown in FIG. 5 can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 5. Additional details relating to facial interfaces with inserted materials and/or structures are described in reference to FIG. 6.

FIG. 6 illustrates a top view of a head-mountable device 600 with a facial interface 604 including an insert 624, according to one example. Although not all components are necessarily shown, the head-mountable device 500 is the same as or similar to the head-mountable devices 400 or 500 of FIGS. 4-5, respectively, as noted by similar reference numbers. For example, the head-mountable device 600 can include an optical component 102, a display frame 105, and bumper(s) 406. The head-mountable device 600 can include the facial interface 604 with a lattice structure including the insert 624 embedded within the lattice structure. In at least one example, the insert 624 can include another material 615 that differs from the material 611 of the facial interface 604. In some examples, the insert 624 can include a material which is inserted into (e.g., injection molded into, dropped into, pressed into, etc.) the material 611 either during or after the additive manufacturing process.

In at least one example, the facial interface 604 can include a material 611 which can be disposed around at least a portion of the insert 624. The material 611 can be characterized by a lattice structure. The insert 624 can be a magnet, an attachment member, or a structural member. For example, the insert 624 can be a magnet which can magnetically couple to at least one of the display frame 105 or the bumper(s) 406 in order to attach the facial interface 604 to the head-mountable device 600. Additionally or alternatively, the insert 624 can be an attachment member, such as a snap button, a hook-and-loop fastener, an adhesive, or other appropriate attachment mechanism to attach the facial interface 604 of the head-mountable device 600. In some examples, the insert 624 can include both a magnet and an attachment member (e.g., the insert can be a magnetic snap button or the like). Both of the magnet and/or the attachment member configurations can allow the facial interface 604 to be removable and interchangeable from the head-mountable device 600.

In additional or alternative examples, the insert 624 can include a structural member. The structural member can be a material with a lattice structure that provides structural rigidity to the facial interface 604. For example, the insert 624 can be a rigid metal or plastic component disposed at least partially within a portion of the insert 624. The insert 624 can be configured as a standard base of the facial insert, as described in reference to FIG. 5.

In at least one example, the insert 624 can be additively manufactured with the facial interface 604. In this case, the insert 624 can be 3D printed in the same printing process with the facial interface 604. In at least one example, the 3D printed material 611 can be stretched over the insert 624. In this case, the insert 624 can be placed or additively manufactured prior to placement of the facial interface 604. In other words, the facial interface 604 can be 3D printed in a separate process than the manufacturing and placement of the insert 624.

Any of the features, components, and/or parts, including the arrangements and configurations thereof shown in FIG. 6 can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 6. Details relating to facial interfaces with internal structures are described with reference to FIGS. 7-9. In particular, details of facial interfaces with vertical beam structures are described in reference to FIG. 7.

FIG. 7 illustrates a rear view of a head-mountable device 700 with a facial interface 704 including vertical beams 726, according to one example. Although not all components are necessarily shown, the head-mountable device 700 is the same as or similar to the head-mountable device 600 of FIG. 6, as noted by similar reference numbers. For example, the head-mountable device 700 can include an optical component 102, a display frame (not illustrated), and bumper(s) (not illustrated). The head-mountable device 700 can include the facial interface 704 with a lattice structure including the vertical beams 726 embedded within the lattice structure. In at least one example, the vertical beams can include another material 715 that differs from the material 711 of the facial interface 704. In other examples, the vertical beams 726 are formed of the same material as other portions of the facial interface 704.

In at least one example, the material 711 includes a first set of vertical beams 726 positioned substantially parallel relative to a contact surface 717 (illustrated in FIG. 6) of the facial interface 704 configured to engage a human face. The contact surface 717 refers to the portion of the facial interface 704 which is compressed against and conforms to the user's face when the user is wearing the head-mountable device 700.

The vertical beams 726 can provide the facial interface 704 with anisotropic properties. For example, the vertical beams 726 can allow the facial interface 704 to be rigid in the X- and Z-directions while being conformable in the Y-direction to accommodate the user's head size, shape, and facial contours.

The vertical beams 726 can be similar to the inserts 724 of FIG. 6, in the sense that they can be 3D printed and/or placed within the facial interface 704.

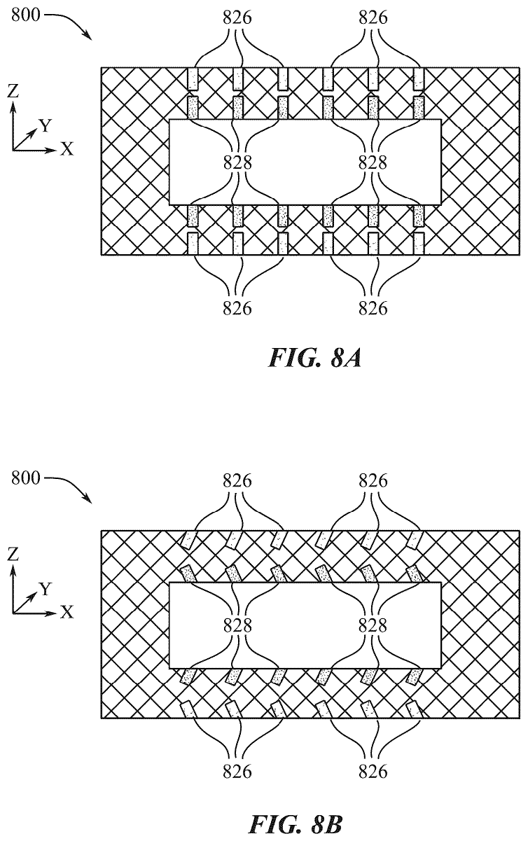

Any of the features, components, and/or parts, including the arrangements and configurations thereof shown in FIG. 7 can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 7. Details of facial interfaces with a first set and a second set of vertical beam structures are described in reference to FIGS. 8A-8B.

FIGS. 8A-8B illustrate rear views of a head-mountable device 800 with a facial interface 804 including a first set of vertical beams 826 and a second set of vertical beams 828, in a non-deformed and a deformed configuration, respectively, according to one example. FIG. 8A illustrates the facial interface 804 wherein there is no applied force to compress the first set of vertical beams 826 and the second set of vertical beams 828. FIG. 8B illustrates the facial interface 804 wherein there is an applied force to compress the first set of vertical beams 826 and the second set of vertical beams 828. Although not all components are necessarily shown, the head-mountable device 800 is the same as or similar to the head-mountable device 700 of FIG. 7, as noted by similar reference numbers. For example, the head-mountable device 800 can include an optical component 102, a display frame (not illustrated), and bumper(s) (not illustrated).

The head-mountable device 800 can include the facial interface 804 with a lattice structure including the first set of vertical beams 826 and the second set of vertical beams 828 embedded within the lattice structure 811. The second set of vertical beams 828 can be stacked relative to the first set of vertical beams 826. The first set of vertical beams 826 and the second set of vertical beams 828 can be configured to laterally buckle. The first set of vertical beams 826 can terminate along a portion of the facial interface 804. The second set of vertical beams 828 can terminate approximately along the same portion of the facial interface 804. The first set of vertical beams 826 and the second set of vertical beams 828 can laterally buckle at their mutual contact points. The lateral buckling between the first set of vertical beams 826 and the second set of vertical beams 828 can provide an anisotropic structure to the lattice structure 811 of the facial interface 804.

In at least one example, the first set of vertical beams 826 and the second set of vertical beams can include materials 815 and 817, respectively. At least one of the materials 815 and 817 can differ from the material 711 of the facial interface 704. In various examples, the materials of the first set of vertical beams 826 and the second set of vertical beams can be either the same or different. In various examples, the lattice structure of the first set of vertical beams 826 and the second set of vertical beams 828 can be either the same or different.

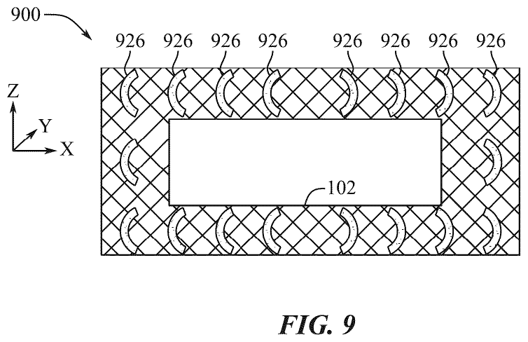

Any of the features, components, and/or parts, including the arrangements and configurations thereof shown in FIGS. 8A-8B can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIGS. 8A-8B. Details of facial interfaces with a C-shaped rib structure are described in reference to FIG. 9.

FIG. 9 illustrates a rear view of a head-mountable device 900 with a facial interface 904 including C-shaped ribs 926, according to one example. Although not all components are necessarily shown, the head-mountable device 900 is the same as or similar to the head-mountable device 800 of FIGS. 8A-8B, as noted by similar reference numbers. For example, the head-mountable device 900 can include an optical component 102, a display frame (not illustrated), and bumper(s) (not illustrated).

The C-shaped ribs 926 can provide an anisotropic structure to the lattice structure 911 of the facial interface 904. For example, the C-shaped ribs 926 can provide compressibility in the Y-direction while being comparatively stiffer or more rigid in the X- and Z-directions. In at least one example, the material and/or the 3D lattice structure of the C-shaped ribs 926 can differ from the material 711 of the facial interface 704.

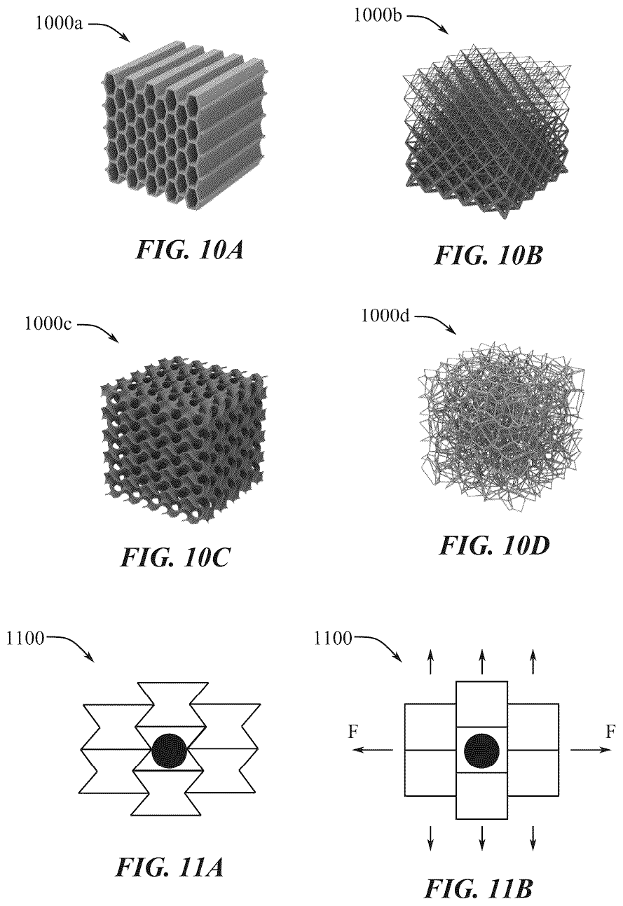

Any of the features, components, and/or parts, including the arrangements and configurations thereof shown in FIG. 9 can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 9. Details of example lattice structures are described with respect to FIGS. 10A-10D and FIGS. 11A-11B.

FIGS. 10A-10B and FIGS. 11A-11B illustrate specific examples of a lattice structure (e.g., a 3D lattice structure) for a facial interface according to one or more examples of the present disclosure. As illustrated in FIGS. 10A-10D and FIGS. 11A-11B, lattice structures can have a geometry or pattern configuration of an auxetic structure, a honeycomb structure, an adjoining sphere structure, or a custom structure based on a stress/strain mapping. Although not all components are necessarily shown, the respective lattice structures 1000a-1000d and 1100 of FIGS. 10A-10D and FIGS. 11A-11B, among others, can be used to form any of the facial interfaces, inserts, vertical beams, or C-shaped ribs described above.

FIG. 10A illustrates a lattice structure 1000a with a geometry or pattern configuration of a honeycomb structure. As used herein, a honeycomb structure is a lattice structure which includes a hexagonal (e.g., triangular) lattice with a two-point basis. In other terms, the honeycomb lattice structure includes two distinct hexagonal lattice structures which are mutually offset. Honeycomb structures, among other lattice structures described below, can provide facial interfaces with lightweight designs while allowing for tailoring of properties, such as rigidity and conformability along various directions. Additionally, properties such as thermal properties and acoustic properties can be tuned by varying or tuning the lattice structures. In some examples, a lattice structure can allow for airflow to the user's face while still offering desired rigidity and conformability properties.

FIG. 10B illustrates a lattice structure 1000b with a geometry or pattern configuration of a beam structure. The beam structure can form various polygonal patterns, such as triangles for desired material properties.

FIG. 10C illustrates a lattice structure 1000c with a geometry or pattern configuration of a gyroid lattice structure. A gyroid lattice structure can also be referred to as a triply periodic minimal surface (TPMS) or a Schwarz surface.

FIG. 10D illustrates a lattice structure 1000d with a geometry or pattern configuration of a stochastic lattice. A stochastic lattice can also be referred to as a Voronoi lattice.

In other examples, a lattice structure can have other geometries or patterns, such as adjoining spheres, triangular pyramid, square pyramid, cubic, etc. Furthermore, lattices can be either periodic, non-periodic, or stochastic. In some examples, a lattice can be trimmed to a certain design (e.g., to wrap around a head of a user) or can be compressed to a certain shape (e.g., by the head of the user). Various lattice structures can be manufactured via additive manufacturing (e.g., 3D printing).

In some examples, various lattice structures can also include a custom structure based on a stress-strain mapping. A stress-strain mapping can indicate mechanical characteristics and properties of the lattice structure, particularly for stress and strain in response to an applied force, vibration, heat, fluid flow, or other physical effect. Examples of a stress-strain mapping can include 3D numerical simulations, such as a finite element analysis mapping. In these or other examples, stress and strain can affect parameters such as deflection, energy absorption (e.g., due to compression, vibration, impacts, etc.), stiffness, and the like.

In at least one example, a lattice structure can include an elastomer material. An elastomer material can include a polymer with viscoelasticity (e.g., both viscosity and elasticity) with a low Young's modulus. Elastomer materials can be characterized by their ability to return to their original shape in the absence of a deforming force. Examples of elastomer materials can include rubbers, styrene-butadiene block copolymers, poly-isoprene, polybutadiene, ethylene propylene rubber, ethylene propylene diene rubber, silicone elastomers, fluoroelastomers, polyurethane elastomers, nitrile rubbers, etc.

Any of the features, components, and/or parts, including the arrangements and configurations thereof shown in FIGS. 10A-10D can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIGS. 10A-10D. Details of auxetic lattice structures are described with respect to FIGS. 11A-11B.

FIGS. 11A-11B illustrates a lattice structure 1100 including a geometry or pattern configuration of an auxetic structure. FIG. 11A illustrates the lattice structure 1100 in the absence of a deforming force. FIG. 11B illustrates the lattice structure 1100 under the influence of a deforming force F.

In at least one example, the lattice structure 311 can include a geometry or pattern configuration of an auxetic structure. As used herein, an auxetic structure refers to a lattice structure that, when stretched (e.g., when a force is applied to extend the lattice structure along a first direction), becomes thicker in a second direction perpendicular to the applied force. More specifically, auxetic structures have a negative Poisson's ratio (a measure of the deformation (expansion or contraction) of a material in directions perpendicular to a direction of loading). For example, as depicted in FIG. 11B, when stretched by the deforming force F, the lattice structure 1100 expands (e.g., becomes thicker, as indicated by vertical arrows) in a direction perpendicular to the deforming force F. In contrast, a non-auxetic structure becomes thinner in a direction perpendicular to the direction of a deforming force.

In some examples, lattice structures that are auxetic can have mechanical properties such as fracture resistance in one or more directions within the lattice. As such, a lattice structure 311 that is auxetic can provide the facial interface 304 with rigidity in one or more directions while being compressible and conformable in the other directions. In one example, the facial interface 304 can be rigid along a top-to-bottom direction and a side-to-side direction of the head 101 to prevent sagging of the facial interface 304 when the head-mountable device is worn by the user. Additionally or alternatively, the facial interface 304 can be compressible and conformable along a front-to-back direction of the head 101 allowing the facial interface 304 to adapt the user's specific head shape and facial contours. In at least some examples, auxetic structures can offer mechanical properties such a high energy absorption, facture resistances, shock absorption, and the like.

Any of the features, components, and/or parts, including the arrangements and configurations thereof shown in FIGS. 11A-11B can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIGS. 11A-11B.

To the extent applicable to the present technology, gathering and use of data available from various sources can be used to improve the delivery to users of invitational content or any other content that may be of interest to them. The present disclosure contemplates that in some instances, this gathered data may include personal information data that uniquely identifies or can be used to contact or locate a specific person. Such personal information data can include demographic data, location-based data, telephone numbers, email addresses, TWITTER® ID's, home addresses, data or records relating to a user's health or level of fitness (e.g., vital signs measurements, medication information, exercise information), date of birth, or any other identifying or personal information.

The present disclosure recognizes that the use of such personal information data, in the present technology, can be used to the benefit of users. For example, the personal information data can be used to deliver targeted content that is of greater interest to the user. Accordingly, use of such personal information data enables users to calculated control of the delivered content. Further, other uses for personal information data that benefit the user are also contemplated by the present disclosure. For instance, health and fitness data may be used to provide insights into a user's general wellness, or may be used as positive feedback to individuals using technology to pursue wellness goals.

The present disclosure contemplates that the entities responsible for the collection, analysis, disclosure, transfer, storage, or other use of such personal information data will comply with well-established privacy policies and/or privacy practices. In particular, such entities should implement and consistently use privacy policies and practices that are generally recognized as meeting or exceeding industry or governmental requirements for maintaining personal information data private and secure. Such policies should be easily accessible by users, and should be updated as the collection and/or use of data changes. Personal information from users should be collected for legitimate and reasonable uses of the entity and not shared or sold outside of those legitimate uses. Further, such collection/sharing should occur after receiving the informed consent of the users. Additionally, such entities should consider taking any needed steps for safeguarding and securing access to such personal information data and ensuring that others with access to the personal information data adhere to their privacy policies and procedures. Further, such entities can subject themselves to evaluation by third parties to certify their adherence to widely accepted privacy policies and practices. In addition, policies and practices should be adapted for the particular types of personal information data being collected and/or accessed and adapted to applicable laws and standards, including jurisdiction-specific considerations. For instance, in the US, collection of or access to certain health data may be governed by federal and/or state laws, such as the Health Insurance Portability and Accountability Act (HIPAA); whereas health data in other countries may be subject to other regulations and policies and should be handled accordingly. Hence different privacy practices should be maintained for different personal data types in each country.

Despite the foregoing, the present disclosure also contemplates embodiments in which users selectively block the use of, or access to, personal information data. That is, the present disclosure contemplates that hardware and/or software elements can be provided to prevent or block access to such personal information data. For example, in the case of advertisement delivery services, the present technology can be configured to allow users to select to “opt in” or “opt out” of participation in the collection of personal information data during registration for services or anytime thereafter. In another example, users can select not to provide mood-associated data for targeted content delivery services. In yet another example, users can select to limit the length of time mood-associated data is maintained or entirely prohibit the development of a baseline mood profile. In addition to providing “opt in” and “opt out” options, the present disclosure contemplates providing notifications relating to the access or use of personal information. For instance, a user may be notified upon downloading an app that their personal information data will be accessed and then reminded again just before personal information data is accessed by the app.

Moreover, it is the intent of the present disclosure that personal information data should be managed and handled in a way to minimize risks of unintentional or unauthorized access or use. Risk can be minimized by limiting the collection of data and deleting data once it is no longer needed. In addition, and when applicable, including in certain health related applications, data de-identification can be used to protect a user's privacy. De-identification may be facilitated, when appropriate, by removing specific identifiers (e.g., date of birth, etc.), controlling the amount or specificity of data stored (e.g., collecting location data a city level rather than at an address level), controlling how data is stored (e.g., aggregating data across users), and/or other methods.

Therefore, although the present disclosure broadly covers use of personal information data to implement one or more various disclosed embodiments, the present disclosure also contemplates that the various embodiments can also be implemented without the need for accessing such personal information data. That is, the various embodiments of the present technology are not rendered inoperable due to the lack of all or a portion of such personal information data. For example, content can be selected and delivered to users by inferring preferences based on non-personal information data or a bare minimum amount of personal information, such as the content being requested by the device associated with a user, other non-personal information available to the content delivery services, or publicly available information.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not target to be exhaustive or to limit the embodiments to the precise forms disclosed. It will be apparent to one of ordinary skill in the art that many modifications and variations are possible in view of the above teachings.

What is claimed is:

1. A head-mountable device, comprising:
a display frame;
an optical component disposed within the display frame;
a facial interface connected to the display frame, the facial interface comprising a lattice structure; and
a strap connected to the display frame.

2. The head-mountable device of claim 1, wherein the lattice structure comprises a geometry or pattern configuration of an auxetic structure, a honeycomb structure, an adjoining sphere structure, or a custom structure based on a stress-strain mapping.

3. The head-mountable device of claim 1, wherein the lattice structure comprises an elastomer material.

4. The head-mountable device of claim 1, wherein the lattice structure comprises a first material and a second material.

5. The head-mountable device of claim 1, further comprising an insert embedded within the lattice structure.

6. The head-mountable device of claim 1, wherein a portion of the lattice structure comprises a first set of directional properties and a second set of directional properties different from the first set of directional properties.

7. The head-mountable device of claim 1, further comprising a rigid bumper connected to the display frame and positioned between the display frame and the facial interface, the rigid bumper defining a fixed gap between the optical component and the facial interface.

8. The head-mountable device of claim 7, wherein:
the lattice structure is a first lattice structure and further comprising a second lattice structure interchangeable with the first lattice structure; and
the first lattice structure and the second lattice structure correspond with the rigid bumper.

9. The head-mountable device of claim 7, wherein facial interface is removably attached to the rigid bumper.

10. The head-mountable device of claim 1, wherein:
a first portion of the lattice structure comprises a base; and
a second portion of the lattice structure comprises a customized portion.

11. A wearable apparatus, comprising:
a display housing;
a display positioned within the display housing; and
a facial interface connected to the display housing, the facial interface comprising a layered material having a repeating geometric arrangement, the layered material having a first portion having a first set of directional properties and a second portion having a second set of directional properties different from the first set of directional properties.

12. The wearable apparatus of claim 11, wherein the repeating geometrical arrangement includes a C-shaped rib.

13. The wearable apparatus of claim 11, wherein the repeating geometrical arrangement comprises a set of vertical beams positioned substantially parallel relative to a contact surface of the facial interface configured to engage a human face.

14. The wearable apparatus of claim 13, wherein:
the set of vertical beams is a first set of vertical beams;
the repeating geometrical arrangement comprises a second set of vertical beams stacked relative to the first set of vertical beams; and
the first set of vertical beams and the second set of vertical beams are configured to laterally buckle in response to a force.

15. The wearable apparatus of claim 11, wherein the facial interface comprises a single-piece unit.

16. A wearable electronic device, comprising:
a head-mountable display;
an insert; and
a facial interface comprising a combination of integrally connected layers defining an ordered pattern disposed around a portion of the insert.

17. The wearable electronic device of claim 16, wherein the insert comprises a magnet, an attachment member, or a structural member.

18. The wearable electronic device of claim 16, wherein the insert is embedded in the facial interface.

19. The wearable electronic device of claim 16, wherein the facial interface is stretched over the insert.

20. The wearable electronic device of claim 16, wherein:
the facial interface comprises a first material; and
the insert comprises a second material that differs from the first material.
